(19) United States
(12) Patent Application Publication
(10) Pub. No.: US 2026/0324522 A1
(43) Pub. Date: Oct. 15, 2026

(54) HYBRID RECESS DEPTH SUBSTRATE STRUCTURE

(71) Applicant: QUALCOMM Incorporated, San Diego, CA (US)

(72) Inventors: Seongryul CHOI, Seongnam (KR); Kuiwon KANG, San Diego, CA (US); Joan Rey Villarba BUOT, Escondido, CA (US)

(21) Appl. No.: 19/298,696

(22) Filed: Aug. 13, 2025

Related U.S. Application Data
(60) Provisional application No. 63/788,652, filed on Apr. 14, 2025.

(51) Int. Cl. H10W 90/00

(52) U.S. Cl. CPC H10W 90/724; H10W 90/734; H10W 90/754

(57) ABSTRACT

Disclosed are die packages. Conventional die packages can include top and bottom substrates. The bottom substrate can be embedded trace substrate (ETS) and can include recesses. The recess depth structure has a limitation for pillar flow out during thermal compression of non-conductive paste, which can result in non-wet defect. To address this issue, it is proposed to provide a substrate that has a mixture of recess depts, i.e., a hybrid depth structure. The bump pads – pads corresponding to die bumps – can have zero depth. In this way, non-wet defect by pillar trap can be avoided.

### CROSS-REFERENCE TO RELATED APPLICATION

The present Application for Patent claims the benefit of U.S. Provisional Patent Application No. 63/788,652 entitled “HYBRID RECESS DEPTH SUBSTRATE STRUCTURE,” filed Apr. 14, 2025, assigned to the assignee hereof, and expressly incorporated herein by reference in its entirety.

### BACKGROUND OF THE DISCLOSURE

### 1. Field of the Disclosure

This disclosure relates generally to die packages or modules, and more specifically, but not exclusively, to packages with hybrid recess depth substrate structure, such as an embedded trace substrate (ETS) structure, and fabrication techniques thereof.

### 2 . Description of the Related Art

Integrated circuit (IC) technology has achieved great strides in advancing computing power through miniaturization of active components. Conventional die packages, such as molded electronic package (MEP), can include top and bottom substrates. The bottom substrate can be an embedded trace substrate (ETS) and can include recesses. The recess depth structure has a limitation for pillar flow out during thermal compression of non-conductive paste. This result in non-wet defects. Accordingly, there is a need for systems, apparatus, and methods that overcome the deficiencies of conventional die packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary die package is disclosed. The die package may comprise a die. The die may comprise one or more die bumps for electrical connections to devices external to the die. The die package may also comprise a package substrate below the die. The package substrate may comprise one or more metal layers. The package substrate may comprise a dielectric layer. The package substrate may also comprise one or more bump pads within the dielectric layer. The one or more bump pads may correspond to the one or more die bumps of the die. The one or more bump pads may electrically couple with the corresponding one or more die bumps. The package substrate may further comprise one or more traces within the dielectric layer. The one or more traces may route signals. An upper surface of at least one bump pad may be above an upper surface of at least one trace.

A method of fabricating a die package is disclosed. The method may comprise providing a die. The die may comprise one or more die bumps for electrical connections to devices external to the die. The method may also comprise forming a package substrate below the die. The package substrate may comprise one or more metal layers. The package substrate may comprise a dielectric layer. The package substrate may also comprise one or more bump pads within the dielectric layer. The one or more bump pads may correspond to the one or more die bumps of the die. The one or more bump pads may electrically couple with the corresponding one or more die bumps. The package substrate may further comprise one or more traces within the dielectric layer. The one or more traces may route signals. An upper surface of at least one bump pad may be above an upper surface of at least one trace.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A illustrates a cross-sectional view of a conventional semiconductor package that includes a die.

FIG. 1B illustrates a scan of a cross-sectional view of a portion a package substrate of a conventional die package.

FIG. 1C illustrates a cross-sectional view of a portion a conventional package substrate.

FIG. 1D illustrates a cross-sectional view of a layer of a conventional package substrate.

FIG. 2A illustrates a cross-sectional view of a die package in accordance with one or more aspects of the disclosure.

FIG. 2B illustrates a scan of a cross-sectional view of a portion a package substrate of a die package in accordance with one or more aspects of the disclosure.

FIG. 2C illustrates a cross-sectional view of a package substrate in accordance with one or more aspects of the disclosure.

FIGS. 3A – 3M illustrate examples of stages of fabricating a package substrate in accordance with one or more aspects of the disclosure.

FIGS. 4 – 5 illustrate flow charts of example methods of manufacturing a die package in accordance with at one or more aspects of the disclosure.

FIG. 6 illustrates various electronic devices which may utilize one or more aspects of the disclosure.

FIG. 7 illustrates a scan of an example die package.

FIG. 8 illustrates a more detailed scan of an example die package.

FIG. 9 illustrates a summary of a conventional semiconductor package and a detailed view of a portion thereof.

FIG. 10 illustrates a summary of an example semiconductor package and a detailed view of a portion thereof in accordance with one or more aspects of the disclosure.

FIG. 11 illustrate examples of stages of fabricating a package substrate in accordance with one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are die packages and methods for fabricating the same. In an aspect, the die package may comprise a die. The die may comprise one or more die bumps for electrical connections to devices external to the die. The die package may also comprise a package substrate below the die. The package substrate may comprise one or more metal layers. The package substrate may comprise a dielectric layer. The package substrate may also comprise one or more bump pads within the dielectric layer. The one or more bump pads may correspond to the one or more die bumps of the die. The one or more bump pads may electrically couple with the corresponding one or more die bumps. The package substrate may further comprise one or more traces within the dielectric layer. The one or more traces may route signals. An upper surface of at least one bump pad may be above an upper surface of at least one trace. In this way, non-wet defects may be reduced or even avoided altogether.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms "a," "an," and "the" are intended to include the plural forms as well, unless the context clearly indicates otherwise. It will be further understood that the terms "comprises," "comprising," "includes," and/or "including," when used herein, specify the presence of stated features, integers, steps, operations, elements, and/or components, but do not preclude the presence or addition of one or more other features, integers, steps, operations, elements, components, and/or groups thereof.

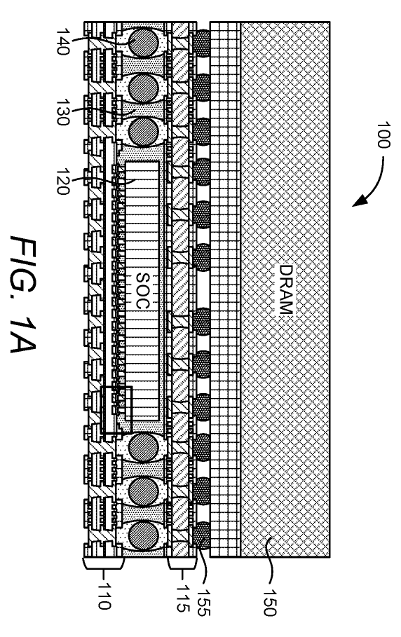

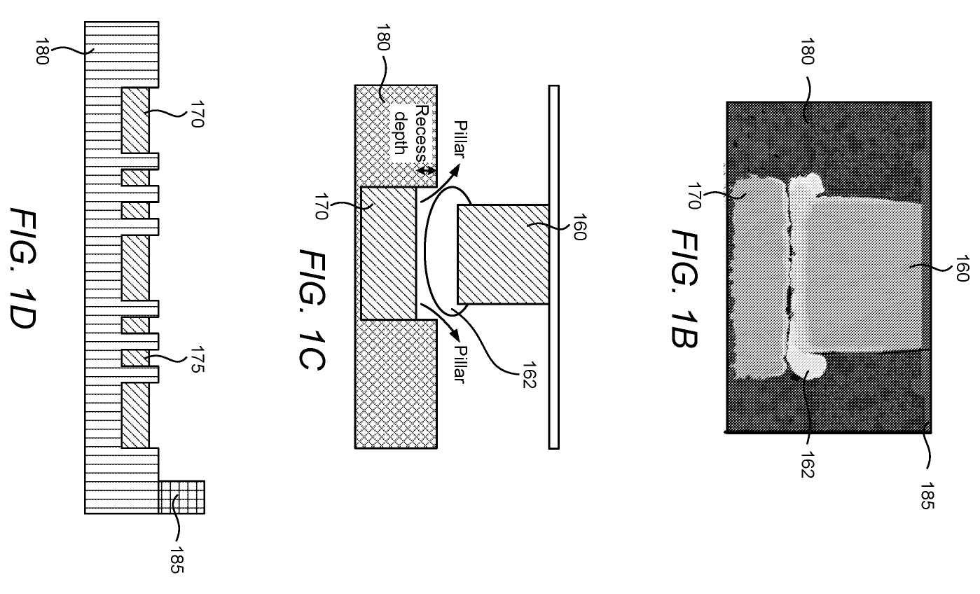

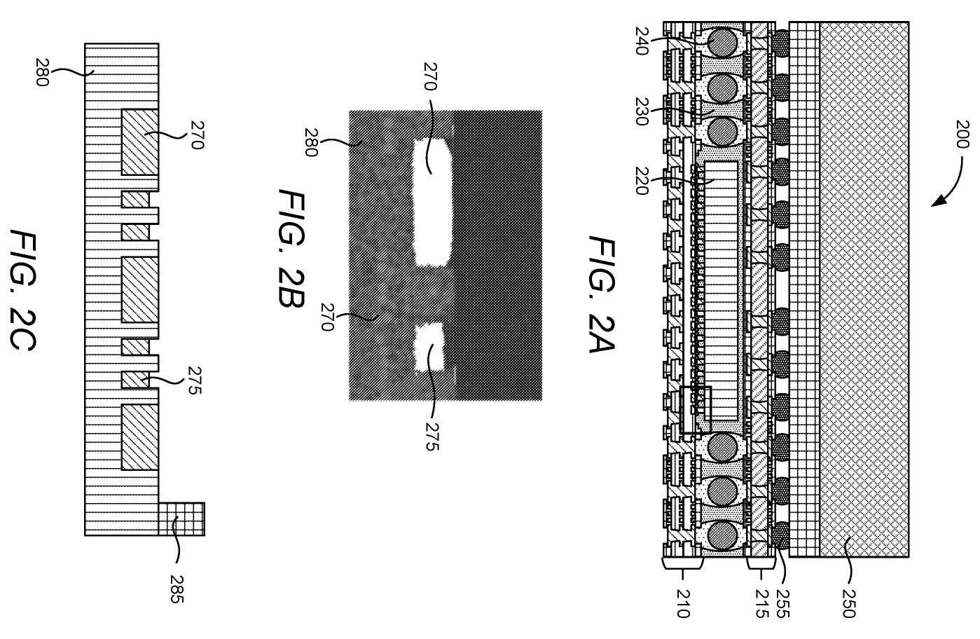

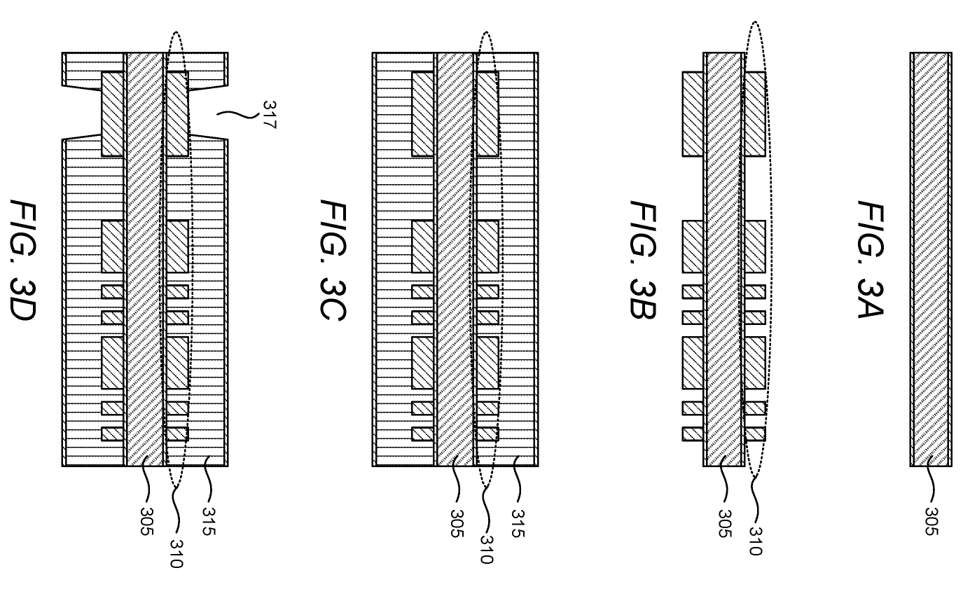

FIG. 1A illustrates a cross-sectional view of a conventional semiconductor package 100. The semiconductor package 100 includes a die 120 and a package substrate 110 below the die 120. A second package substrate 115 is on the die 120. A second die 150 is provided above the second package substrate 115. A ball grid array (BGA) 155 comprising a plurality of solder balls is physically provided in between the die 120 and the second die 150. Mold 130 encapsulates the die 120 (which also may be referred to as the first die 120), and through-mold-vias (TMV) 140 is formed within the mold 130. Combination of the package substrate 110, the die 120, the mold 130, and the TMV 140 may be referred to as a molded electronic package (MEP) or a die package.

A portion of the semiconductor package 100 is highlighted in FIG. 1A with a rectangle. The highlighted portion includes a portion of the die 120 and a portion of the package substrate 110. FIG. 1B illustrates a scan the highlighted portion, FIG. 1C illustrates cross-section of the highlighted portion, and FIG. 1D illustrates a layer of the package substrate 110.

As seen in FIG. 1D, the layer of the conventional package substrate 110 includes a dielectric layer 180, a solder resist (SR) 185 on the dielectric layer 180, a plurality of bump pads 170 and a plurality of traces 175. The plurality of bump pads 170 and the plurality of traces 175 are formed within the dielectric layer 180. Due to etching that takes place when fabricating the conventional package substrate 110, upper surfaces of the plurality of bump pads 170 and of the plurality of traces 175 are lower than the upper surface of the dielectric layer 180. As a result, recesses are formed. Trace recesses – recesses formed by traces 175 – may be tolerated.

However, bump pad recesses – recesses formed by the bump pads 170 – can present problematic issues. Note that the die 120 includes one or more die bumps 160 configured to carry signals from/to the die 120. The bump pads 170 correspond to die bumps 160. That is, the bump pads 170 are electrically coupled to the corresponding die bumps 160 through solders 162 physically provided between the bump pads 170 and the die bumps 160. When fabricating the semiconductor package 100, non-conductive paste (NCP) can be provided on the surface of the dielectric layer 180, which means that both the bump pad recesses and the trace recesses can be filled with the NCP. When bonding, thermal compression can be used to electrically couple the bump pads 170 and the die bumps 160. However, as seen in FIGS. 1B and 1C, this can limit pillar flow out, which in turn can cause non-wet defects.

To address these and other issues of the conventional die package, it is proposed to provide a hybrid recess depth structure in a package substrate. In particular, it is proposed reduce or even entirely remove the bump pad recesses. This can enable easier pillar flow out. As a result, occurrences of non-wet defect (e.g., due to pillar trap) can be reduced or even eliminated altogether.

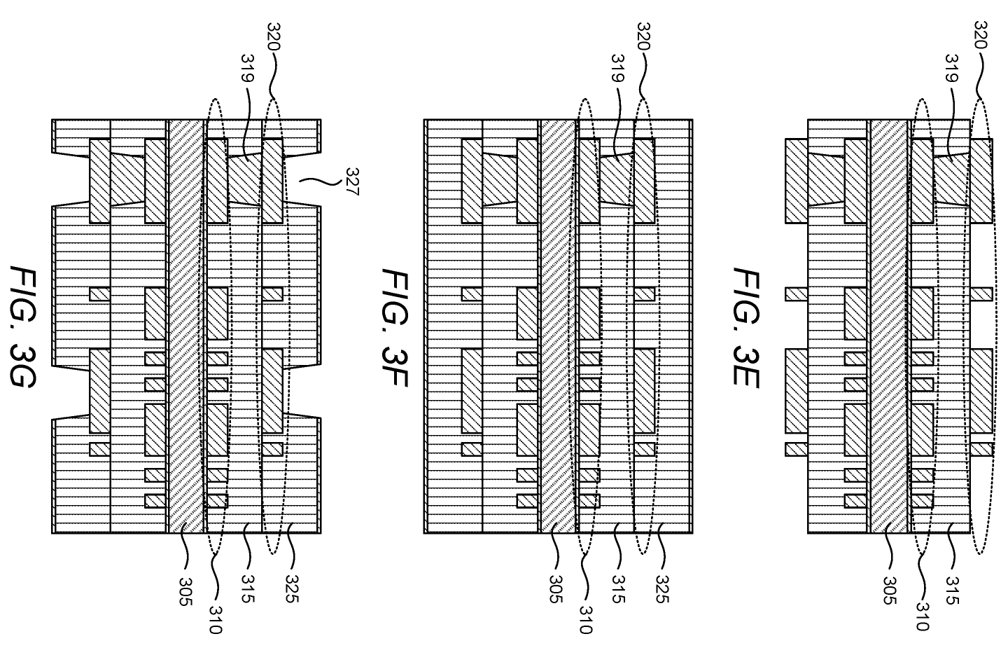

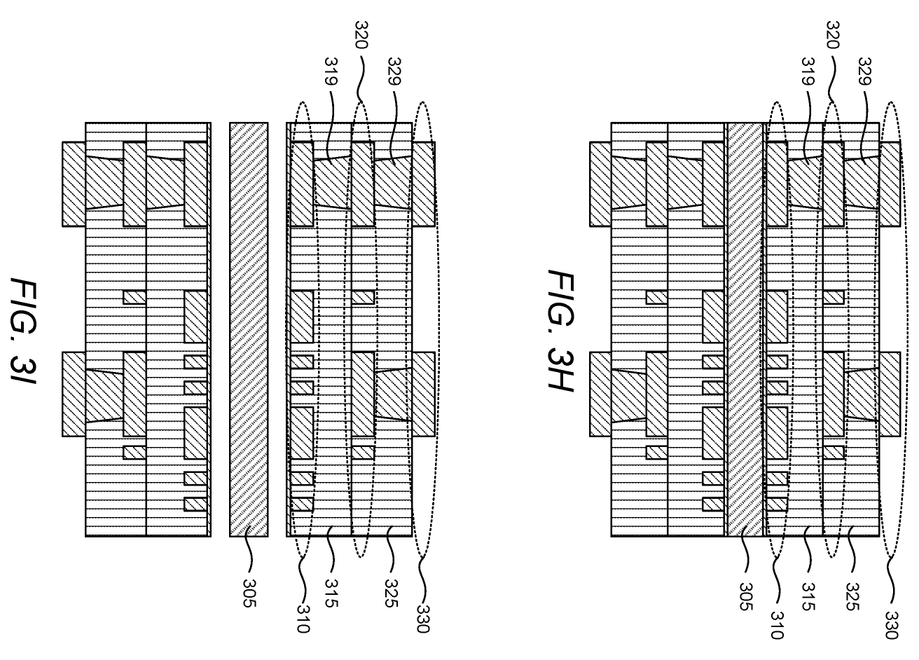

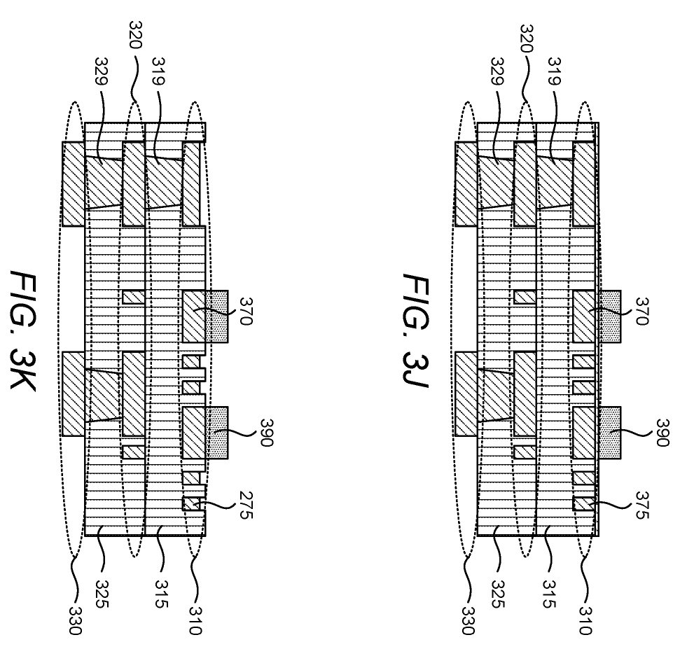

FIG. 2A illustrates a cross-sectional view of a semiconductor package 200 that includes an MEP. The semiconductor package 200 may include a die 220 (may also be referred to as a first die 220). Thus, the semiconductor package 200 may also be referred to as a die package 200. A package substrate 210 may be formed below the die 220. The die 220 may be any active die such as a system-on-chip (SoC), memory, etc. The SoC may be a chip that includes any combination of one or more central processing units (CPU), one or more graphics processing units (GPU), and so on.

A second package substrate 215 may be formed on the die 220, and a second die 250 may be provided above the second package substrate 215. The second package substrate 215 may also be referred to as an interposer 215. A ball grid array (BGA) 255 comprising a plurality of solder balls may be physically provided in between the die 220 and the second die 250. The BGA 255 may enable the second die 250 to be connected, e.g., electrically coupled, to the package substrate 210 through the interposer 215.

The second die 250 may also be any active die, e.g., SoC, memory, etc. For example, the second die 250 may comprise one or more memory chips such as dynamic random access memory (DRAM). The memory, including the DRAMs, may comprise a logic die that includes any combination of a neural processing unit (NPU), memory controller, etc. The DRAMs may be connected together and to the interposer 215 through interconnects such as wire bonds, through-substrate-vias (TSV), hybrid bonding, and so on. In general, the die package 200 may be applicable to high tier mobility applications. In particular, the die package 200 may be applicable to high tier mobility applications with AI capabilities.

A mold 230 may be formed on the package substrate 210, and may encapsulate the die 220. One or more through-mold-vias (TMV) 240 may be formed within the mold 230. Combination of the package substrate 210, the die 220, the mold 230, and the TMV 240 may be referred to as a molded electronic package (MEP) or a die package. The interposer 215 may be formed on the mold 230, and the second die 250 along with the BGA 255 may be provided on the interposer 215.

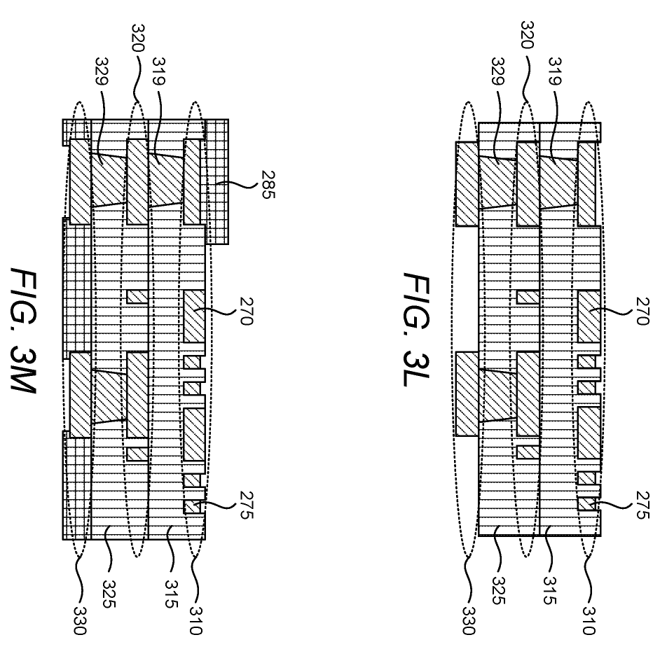

A portion of the die package 200 is highlighted in FIG. 2A with a rectangle. The highlighted portion includes a portion of the die 220 and a portion of the package substrate 210. FIG. 2B illustrates a scan the highlighted portion and FIG. 2C illustrates a layer of the package substrate 210. As will be demonstrated in FIGS. 3A – 3M, the package substrate 210 may include multiple dielectric layers. The dielectric layers may be prepreg (PPG) materials, organic materials, laminate materials, etc. There may be multiple metal layers (e.g., M1, M2, M3, etc.) formed on or within the multiple dielectric layers. Each metal layer M1, M2, M3, etc. may include one or more pads and/or one or more traces. The traces within each dielectric layer may serve to route signals. Each dielectric layer may further include one or more vias. The one or more vias of one dielectric layer may electrically couple the pads of the metal layer within another dielectric layer immediately above or below the one dielectric layer.

Referring back to FIG. 2C, a layer of the package substrate 210 may include a dielectric layer 280, a plurality of bump pads 270 and a plurality of traces 275. In an aspect, the dielectric layer 280 may be a first dielectric layer of the package substrate 210, and the plurality of bump pads 270 and the plurality of traces 275 may be formed from a first metal layer M1 of the package substrate 210. The first metal layer M1 may be the metal layer that is closest in proximity to the die 220 among the metal layers M1, M2, M3, etc. of the package substrate 210.

The plurality of bump pads 270 and the plurality of traces 275 may be formed within the dielectric layer 280, and may be formed from conductive metals, e.g., copper (Cu). The bump pads 270 may electrically couple with die bumps 260 of the die 220, while the traces 275 may route signals. In an aspect, the bump pads 270 may be wider than the traces 275.

While not shown, there may be solders between the die bumps 260 of the die 220 and the bump pads 270 corresponding to the die bumps 260. In an aspect, the solder may be in contact with the die bump 260 above and in contact with the corresponding bump pad 270 below. The die bumps 260 may vertically overlap, at least partially, with the corresponding bump pads 270.

Due to etching that takes place when fabricating the package substrate 210, recesses may be formed by the plurality of traces 275. That is, upper surfaces of the traces 275 may be at a lower level than the upper surface of the dielectric layer 280. The depth of the trace recess (the recesses formed by the traces 275) may be 4 ± 2 µm as seen in FIG. 2B. The trace recesses may be tolerated.

However, there may be little to no recesses formed by bump pads 270. That is, there may be no bump pad recesses. For example, as seen in FIGS. 2B and 2C, the upper surfaces of the bump pads 270 may be at a same level as the upper surface of the dielectric layer 280. Having no bump pad recess is technically advantageous in that when TCNCP is performed, pillar can flow out easily and thus minimize or even prevent occurrences of non-wet defects.

While not shown, it should be noted that the height of the bumps 270 is not so limited. For example, the upper surfaces of the bump pads 270 may be at a higher level than the upper surface of the dielectric layer 280. When TCNCP is performed, the non-wet defect may be prevented more easily. In another example, the upper surfaces of the one or more traces is at a lower level than the upper surface of the dielectric layer. That is, some bump pad recesses may be formed. However, in this instance, the depth of the bump pad recesses may be small (e.g., less than the trace recess depth, i.e., less than 2 µm) such that pillar flow out still occurs easily when TCNCP is performed. In general, the heights of the bump pads 270 may be above the heights of the traces 275. That is, the upper surfaces of the bump pads 270 may be higher than the upper surfaces of the traces 275.

FIGS. 3A – 3M illustrate examples of stages of fabricating a package substrate, such as the package substrate 210, in accordance with one or more aspects of the disclosure. In these figures, forming die packages on both sides of a carrier is shown. However, this is an example, and should not be taken to be a limitation. That is, it is also contemplated that die packages may be formed on one side of a carrier. Also, in this instance, description of the process taken on the side above the carrier will be provided. However, similar processes may be performed on the side below the carrier.

FIG. 3A illustrates a stage in which a metal (e.g., Cu) may be formed on surfaces of a carrier (e.g., detach carrier foil (DCF)) 305.

FIG. 3B illustrates a stage in which conductive metal (e.g., Cu) may be deposited on the carrier 305 and patterned to form the first metal layer M1310. The patterning may form the basic shapes of the bump pads 270 and the traces 275.

FIG. 3C illustrates a stage in which a dielectric material (e.g., prepreg (PPG)) may be deposited and/or laminated on the carrier 305 to form a first dielectric layer 315, which may correspond to the dielectric layer 280 of FIG. 2C.

FIG. 3D illustrates a stage in which first via holes 317 may be formed for M1 – M2 connections.

FIG. 3E illustrates a stage in which conductive metal (e.g., Cu) may be deposited and patterned to form first vias 319 and a second metal layer M2320 on the first dielectric layer 315.

FIG. 3F illustrates a stage in which a dielectric material (e.g., prepreg (PPG)) may be deposited and/or laminated on the first dielectric layer 315 to form the second dielectric layer 325. The second metal layer M2320 may be within the second dielectric layer 325.

FIG. 3G illustrates a stage in which second via holes 327 may be formed for M2 – M3 connections.

FIG. 3H illustrates a stage in which conductive metal (e.g., Cu) may be deposited and patterned to form second vias 329 and a third metal layer M3330 on the second dielectric layer 325.

FIG. 3I illustrates a stage in which upper and lower package substrates are separated from the carrier 305.

In FIGS. 3J – 3M, processes are performed on one of the package substrates to form the hybrid recess depths are illustrated. The package substrates of FIGS. 3J – 3M may represent the package substrate below the carrier 305 in FIG. 3I or may represent a flipped version of the package substrate above the carrier 305 in FIG. 3I.

FIG. 3J illustrates a stage in which a mask 390 may be formed on upper surface of the first metal layer M1310 to cover one or more bump pad metals 370 (which correspond to the bump pads 270). The mask 390 may be formed from a dry film resist (DFR), a photo resist (PR), etc. Note that the one or more trace metals 375 (which correspond to the traces 275) may be left exposed.

FIG. 3K illustrates a stage in which the exposed surfaces of the first metal layer M1310 may be etched. As a result, the one or more traces 275, with corresponding trace recesses, may be formed.

FIG. 3L illustrates a stage in which the mask 390 may be removed. As a result, the one or more bump pads 270 may be formed.

FIG. 3M illustrates a stage in which solder resist 285 may be formed on upper surface of the first dielectric layer 315 (on upper surface of the dielectric layer 280). Alternatively or in addition thereto, solder resist 285 may also be formed on a lower surface of the last metal layer (M3 in this instance).

While two dielectric and three metal layers are illustrated in FIGS. 3A – 3M, it should be noted that the package substrate 210 can have any number of dielectric layers and any number of metal layers.

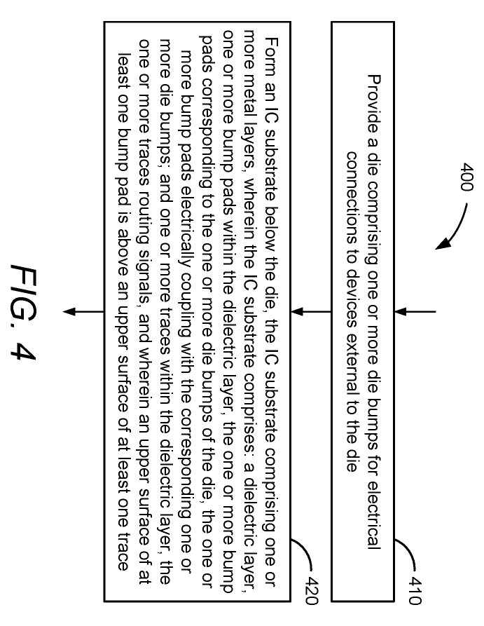

FIG. 4 illustrates a flow chart of an example method 400 of fabricating a die package, such as the die package 200, in accordance with at one or more aspects of the disclosure.

In block 410, a die 220 may be provided. The die 220 may include one or more die bumps 260 to enable electrical connections to devices external to the die 220.

In block 420, a package substrate 210 may be formed below the die 220. The package substrate 210 may include one or more metal layers. In particular, the package substrate 210 may comprise a dielectric layer 280. The package substrate 210 may also comprise one or more bump pads 270 within the dielectric layer 280. The one or more bump pads 270 may correspond to the one or more die bumps 260 of the die 220. The one or more bump pads 270 may electrically couple with the corresponding one or more die bumps 260. The package substrate may further comprise one or more traces 275 within the dielectric layer 280. The one or more traces 275 may route signals. An upper surface of at least one bump pad 270 may be above an upper surface of at least one trace 275.

FIG. 5 illustrates a flow chart of an example process to perform block 420 of FIG. 4. FIG. 5 may correspond to the stages illustrated in FIGS. 3J – 3M. That is, the dielectric layer 280 may be a first dielectric layer 315 among one or more dielectric layers 315, 325 of the package substrate 210. The first dielectric layer 315 (i.e., the dielectric layer 280) may be a topmost dielectric layer of the one or more dielectric layers 315, 325. Also, the first metal layer M1310 of the package substrate 210 may be formed within the first dielectric layer 315 and may comprise one or more bump pad metals 370 and one or more trace metals 375 (e.g., see FIG. 3J).

In block 510, a mask 390 may be formed on upper surface of the first metal layer M1310 to cover one or more bump pad metals 370. The one or more trace metals 375 may be left exposed.

In block 520, the exposed surfaces of the first metal layer M1 may be etched. As a result, the one or more traces 275, with corresponding trace recesses, may be formed.

In block 530, the mask 390 may be removed to form the one or more bump pads 270.

FIG. 3M illustrates a stage in which solder resist 285 may be formed at least on an upper surface of the first dielectric layer (on an upper surface of the dielectric layer 280).

The following should be noted regarding the flow indicated in FIGS. 4 – 5. Unless otherwise indicated, the flow of blocks do not necessarily limit the ordering in which the blocks may be performed. In other words, the blocks may be performed in any order that is logical.

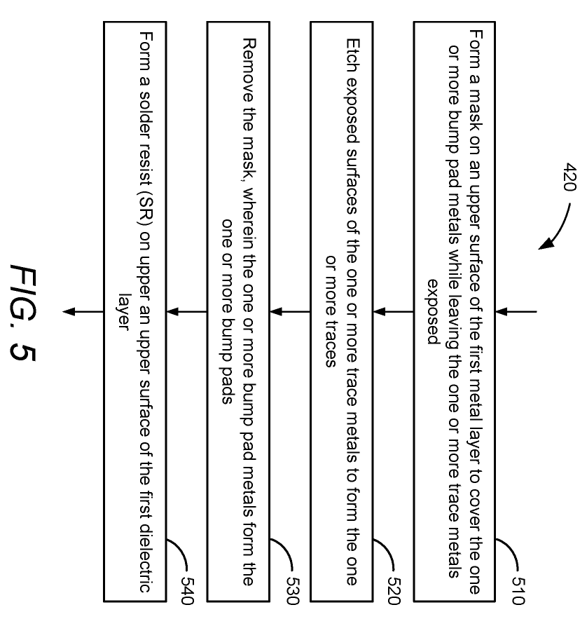

FIG. 6 illustrates various apparatuses (e.g., electronic devices) in which any of the semiconductor devices and/or electronic packages disclosed herein may be integrated, according to aspects of the disclosure. In an aspect, the semiconductor devices and/or electronic packages 600, such as die packages, may be integrated into user equipment (UE), including, by way of example and not limitation, a mobile phone device 602, a laptop computer device 604, a fixed-location terminal device 606, or a wearable device 608.

In other aspects, the semiconductor devices and/or electronic packages 600 may be integrated into electronic devices utilized in automotive applications. Such devices may include, by way of example and not limitation, sensors, controllers, processors, infotainment devices, and the like, which may be installed in a vehicle 610.

In yet other aspects, the semiconductor devices and/or electronic packages 600 may be integrated into a short-range device (SRD) 612. The SRD 612 may comprise, for example, one or more sensors, robotic machines, product code identifiers, electronic pricing and display labels, Internet of Things (IoT) devices, radio frequency identification (RFID) devices, Bluetooth Low Energy® (BLE) devices, or other similar devices.

In further aspects, the semiconductor devices and/or electronic packages 600 may be integrated into a server 614. The server 614 may comprise a computer system configured to provide services, data, or resources to other computers over a network. Such a server 614 may include one or more processors, integrated memory devices, power supplies, or other components mounted in one or more racks.

In yet other aspects, the semiconductor devices and/or electronic packages 600 may be integrated into a data center 616. The data center 616 may comprise a facility configured with one or more servers, storage devices, networking devices, and other supporting devices for storing, processing, and managing data.

The semiconductor devices and/or electronic packages 600 disclosed herein may be fabricated in various package configurations, including, but not limited to, side-by-side (SxS) packages, system-in-package (SiP) configurations, integrated circuit (IC) packages, package-on-package (PoP) devices, or any other suitable packaging configuration, whether disclosed herein or known in the art.

It will be appreciated, based on the teachings of the present disclosure, that the various apparatuses 602, 604, 606, 608, 610, 612, 614, and 616 illustrated in FIG. 6 are merely exemplary. Other apparatuses in which the semiconductor devices and/or electronic packages 600 may be integrated include, without limitation, mobile devices, hand-held personal communication system (PCS) units, portable data units (e.g., personal digital assistants), global positioning system (GPS)-enabled devices, navigation devices, set-top boxes, music players, video players, entertainment units, fixed-location data units, communication devices, smartphones, tablets, computers, wearable devices, servers, routers, memory devices, data centers, automotive electronic devices, Internet of Things (IoT) devices, or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

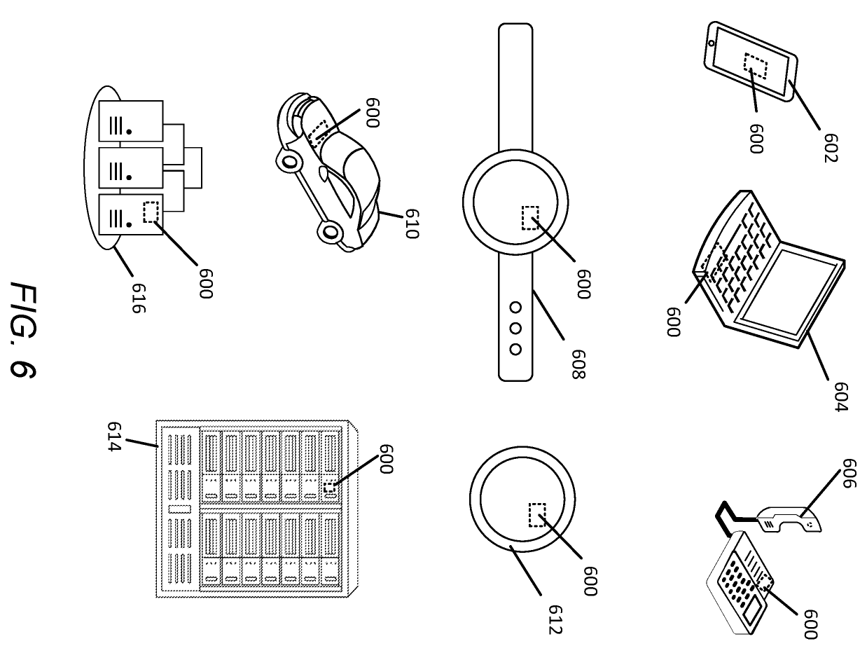

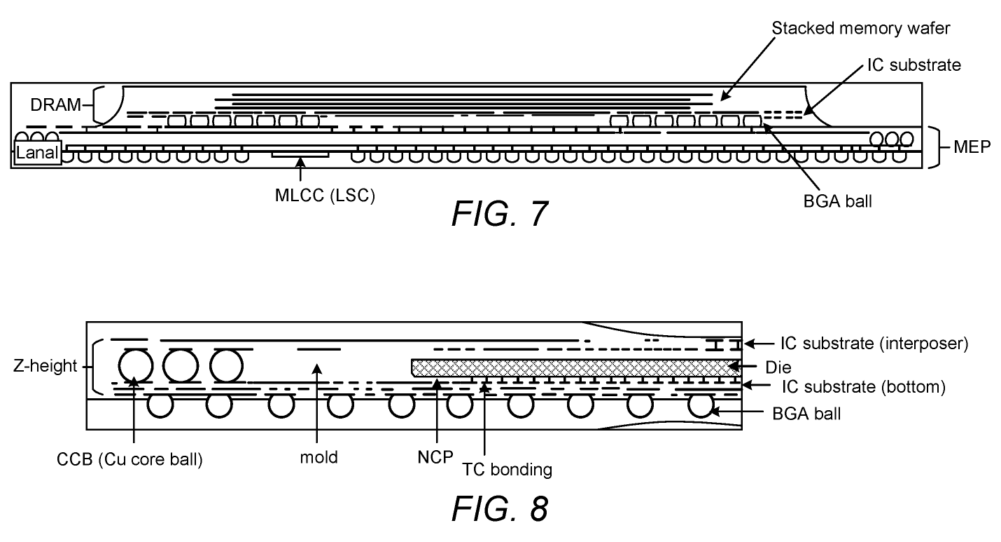

FIGS. 7 and 8 illustrate scans of semiconductor packages (PoP), such as die packages, in which the subject matter of the current disclosure may be relevant.

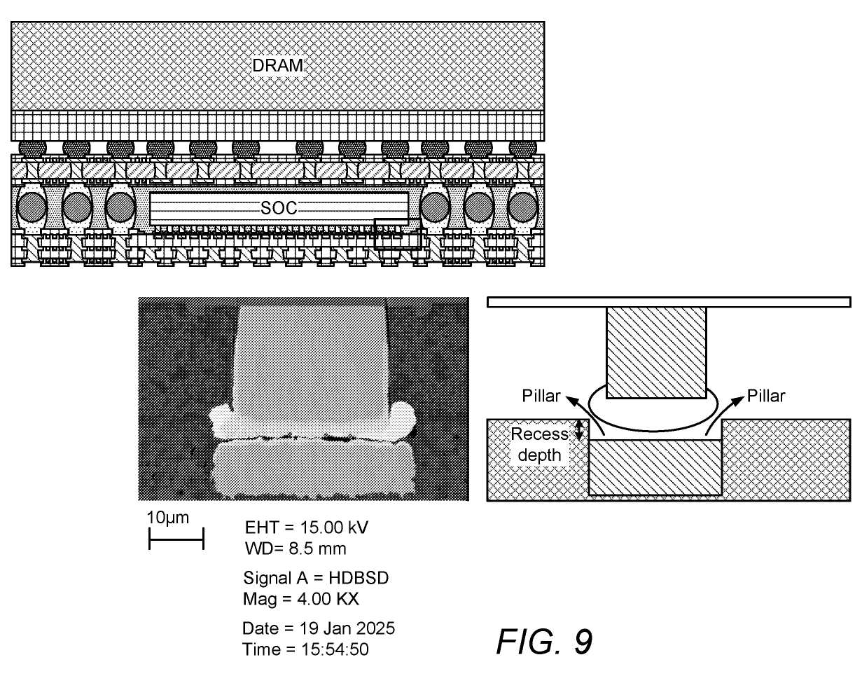

FIG. 9 illustrates issues related to conventional die packages.

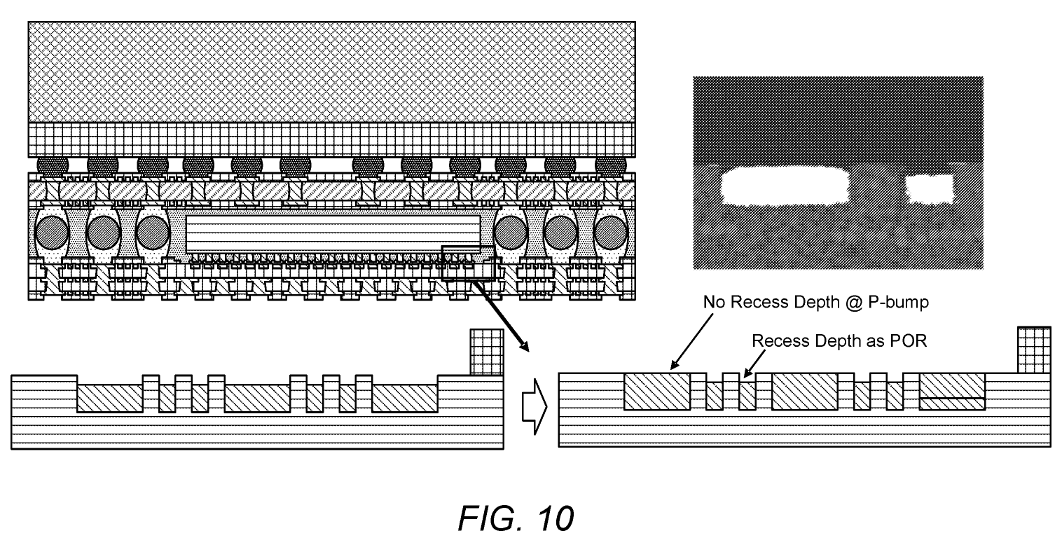

FIG. 10 illustrates an example of a die package in accordance with one or more aspects of the disclosure. FIG. 10 also illustrates a transition from conventional package substrate (with bump pad recesses) to a proposed package substrate (without bump pad recesses).

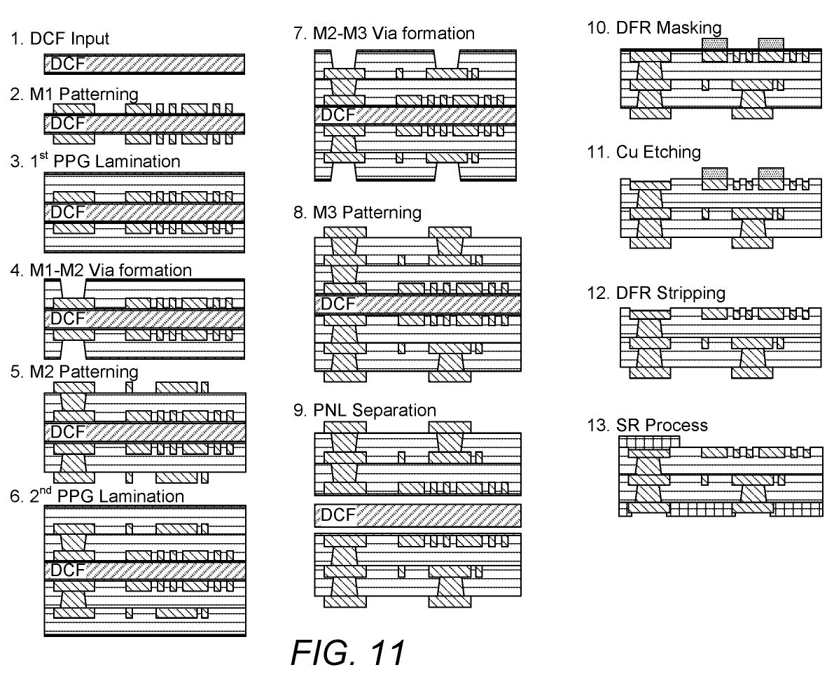

FIG. 11 illustrates a summary of the stages of fabricating the package substrate.

Implementation examples are described in the following numbered clauses:

Clause 1: A die package, comprising: a die comprising one or more die bumps for electrical connections to devices external to the die; and a package substrate below the die, the package substrate comprising one or more metal layers, wherein the package substrate comprises: a dielectric layer; one or more bump pads within the dielectric layer, the one or more bump pads corresponding to the one or more die bumps of the die, the one or more bump pads electrically coupling with the corresponding one or more die bumps; and one or more traces within the dielectric layer to route signals, and wherein an upper surface of at least one bump pad is above an upper surface of at least one trace.

Clause 2: The die package of clause 1, wherein the upper surface of the at least one bump pad is at a same level as an upper surface of the dielectric layer.

Clause 3: The die package of any of clauses 1-2, wherein the upper surface of the at least one bump pad is at a higher level than an upper surface of the dielectric layer.

Clause 4: The die package of any of clauses 1-3, wherein the upper surface of the at least one trace is at a lower level than an upper surface of the dielectric layer to form a recess.

Clause 5: The die package of any of clauses 1-4, wherein the at least one bump pad and the at least one trace formed from a first metal layer (M1) of the package substrate.

Clause 6: The die package of any of clauses 1-5, further comprising: a solder between the at least one bump pad and at least one die bump corresponding to the at least one bump pad, wherein the at least one bump pad and the at least one die bump are in direct contact with the solder.

Clause 7: The die package of any of clauses 1-6, wherein the at least one bump pad is wider than the at least one trace.

Clause 8: The die package of any of clauses 1-7, wherein the at least one bump pad vertically overlaps and corresponding at least one die bump vertically overlap.

Clause 9: The die package of any of clauses 1-8, further comprising: a mold on the package substrate, wherein the mold encapsulates the die; an interposer on the mold; one or more through-mold-vias (TMV) within the mold; and a second die provided on the interposer, the second die comprising a ball grid array (BGA), wherein the second die is connected to the package substrate through the BGA, the interposer, and the one or more TMVs.

Clause 10: The die package of clause 9, wherein the second die comprises one or more dynamic random access memories (DRAM).

Clause 11: The die package of clause 10, wherein the second die further comprises a logic die that comprises any combination of a neural processing unit (NPU) and a memory controller.

Clause 12: The die package of any of clauses 9-11, wherein the second die is connected to the interposer through any combination of wire bonds, through-substrate-vias (TSV), and hybrid bonding.

Clause 13: The die package of any of clauses 1-12, wherein the die package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.

Clause 14: A method of fabricating a die package, the method comprising: providing a die comprising one or more die bumps for electrical connections to devices external to the die; and forming a package substrate below the die, the package substrate comprising one or more metal layers, wherein the package substrate comprises: a dielectric layer; one or more bump pads within the dielectric layer, the one or more bump pads corresponding to the one or more die bumps of the die, the one or more bump pads electrically coupling with the corresponding one or more die bumps; and one or more traces within the dielectric layer to route signals, and wherein an upper surface of at least one bump pad is above an upper surface of at least one trace.

Clause 15: The method of clause 14, wherein the upper surface of the at least one bump pad is at a same level as an upper surface of the dielectric layer.

Clause 16: The method of any of clauses 14-15, wherein the upper surface of the at least one bump pad is at a higher level than an upper surface of the dielectric layer.

Clause 17: The method of any of clauses 14-16, wherein the upper surface of the at least one trace is at a lower level than an upper surface of the dielectric layer to form a recess.

Clause 18: The method of any of clauses 14-17, wherein the at least one bump pad and the at least one trace formed from a first metal layer (M1) of the package substrate.

Clause 19: The method of any of clauses 14-18, further comprising: forming a solder between the at least one bump pad and at least one die bump corresponding to the at least one bump pad, wherein the at least one bump pad and the at least one die bump are in direct contact with the solder.

Clause 20: The method of any of clauses 14-19, wherein the at least one bump pad is wider than the at least one trace.

Clause 21: The method of any of clauses 14-20, wherein the at least one bump pad vertically overlaps and corresponding at least one die bump vertically overlap.

Clause 22: The method of any of clauses 14-21, wherein the dielectric layer is a first dielectric layer among one or more dielectric layers of the package substrate, the first dielectric layer being a topmost dielectric layer of the one or more dielectric layers, wherein a first metal layer of the package substrate is formed within the first dielectric layer and comprises one or more bump pad metals and one or more trace metals, and wherein forming the package substrate comprises: forming a mask on an upper surface of the first metal layer to cover the one or more bump pad metals while leaving the one or more trace metals exposed; etching exposed surfaces of the one or more trace metals to form the one or more traces; removing the mask, wherein the one or more bump pad metals form the one or more bump pads; and forming a solder resist (SR) on upper an upper surface of the first dielectric layer.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink / reverse or downlink / forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms "connected," "coupled," or any variant thereof, mean any connection or coupling, either direct or indirect, between elements, and can encompass a presence of an intermediate element between two elements that are "connected" or "coupled" together via the intermediate element unless the connection is expressly disclosed as being directly connected.

Any reference herein to an element using a designation such as "first," "second," and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A die package, comprising:
a die comprising one or more die bumps for electrical connections to devices external to the die; and
a package substrate below the die, the package substrate comprising one or more metal layers,
wherein the package substrate comprises:
a dielectric layer;
one or more bump pads within the dielectric layer, the one or more bump pads corresponding to the one or more die bumps of the die, the one or more bump pads electrically coupling with the corresponding one or more die bumps; and
one or more traces within the dielectric layer to route signals, and
wherein an upper surface of at least one bump pad is above an upper surface of at least one trace.

2. The die package of claim 1, wherein the upper surface of the at least one bump pad is at a same level as an upper surface of the dielectric layer.

3. The die package of claim 1, wherein the upper surface of the at least one bump pad is at a higher level than an upper surface of the dielectric layer.

4. The die package of claim 1, wherein the upper surface of the at least one trace is at a lower level than an upper surface of the dielectric layer to form a recess.

5. The die package of claim 1, wherein the at least one bump pad and the at least one trace formed from a first metal layer (M1) of the package substrate.

6. The die package of claim 1, further comprising:
a solder between the at least one bump pad and at least one die bump corresponding to the at least one bump pad,
wherein the at least one bump pad and the at least one die bump are in direct contact with the solder.

7. The die package of claim 1, wherein the at least one bump pad is wider than the at least one trace.

8. The die package of claim 1, wherein the at least one bump pad and corresponding at least one die bump vertically overlap.

9. The die package of claim 1, further comprising:
a mold on the package substrate, wherein the mold encapsulates the die;
an interposer on the mold;
one or more through-mold-vias (TMV) within the mold; and
a second die provided on the interposer, the second die comprising a ball grid array (BGA),
wherein the second die is connected to the package substrate through the BGA, the interposer, and the one or more TMVs.

10. The die package of claim 9, wherein the second die comprises one or more dynamic random access memories (DRAM).

11. The die package of claim 10, wherein the second die further comprises a logic die that comprises any combination of a neural processing unit (NPU) and a memory controller.

12. The die package of claim 9, wherein the second die is connected to the interposer through any combination of wire bonds, through-substrate-vias (TSV), and hybrid bonding.

13. The die package of claim 1, wherein the die package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.

14. A method of fabricating a die package, the method comprising:
providing a die comprising one or more die bumps for electrical connections to devices external to the die; and
forming a package substrate below the die, the package substrate comprising one or more metal layers,
wherein the package substrate comprises:
a dielectric layer;
one or more bump pads within the dielectric layer, the one or more bump pads corresponding to the one or more die bumps of the die, the one or more bump pads electrically coupling with the corresponding one or more die bumps; and
one or more traces within the dielectric layer to route signals, and
wherein an upper surface of at least one bump pad is above an upper surface of at least one trace.

15. The method of claim 14, wherein the upper surface of the at least one bump pad is at a same level as or at a higher level than an upper surface of the dielectric layer.

16. The method of claim 14, wherein the upper surface of the at least one trace is at a lower level than an upper surface of the dielectric layer to form a recess.

17. The method of claim 14, wherein the at least one bump pad and the at least one trace formed from a first metal layer (M1) of the package substrate.

18. The method of claim 14, further comprising:
forming a solder between the at least one bump pad and at least one die bump corresponding to the at least one bump pad,
wherein the at least one bump pad and the at least one die bump are in direct contact with the solder.

19. The method of claim 14, wherein the at least one bump pad is wider than the at least one trace.

20. The method of claim 14,
wherein the dielectric layer is a first dielectric layer among one or more dielectric layers of the package substrate, the first dielectric layer being a topmost dielectric layer of the one or more dielectric layers,
wherein a first metal layer of the package substrate is formed within the first dielectric layer and comprises one or more bump pad metals and one or more trace metals, and
wherein forming the package substrate comprises:
forming a mask on an upper surface of the first metal layer to cover the one or more bump pad metals while leaving the one or more trace metals exposed;
etching exposed surfaces of the one or more trace metals to form the one or more traces;
removing the mask, wherein the one or more bump pad metals form the one or more bump pads; and
forming a solder resist (SR) on upper an upper surface of the first dielectric layer.
